(19) United States
(12) Patent Application Publication
(10) Pub. No.: US 2016/0365469 A1
(43) Pub. Date: Dec. 15, 2016

(54) SOLAR CELL ARRAY

(71) Applicant: SOLARWORLD INNOVATIONS GMBH, Freiberg (DE)

(72) Inventors: Stefan STECKEMETZ, Freiberg (DE); Bernd BITNAR, Bannewitz (DE); Alexander FÜLLE, Kirchberg (DE); Christian KOCH, Pohl-Ruppertsgrun (DE)

(73) Assignee: SOLARWORLD INNOVATIONS GMBH, Freiberg (DE)

(21) Appl. No.: 15/172,924

(22) Filed: Jun. 3, 2016

(30) Foreign Application Priority Data
Jun. 9, 2015 (DE) 202015004065.9

(51) Int. Cl. H01L 31/05; H01L 31/0236; H01L 31/068; H01L 31/0224; H01L 31/02

(52) U.S. Cl. CPC H01L 31/0516; H01L 31/022458; H01L 31/0201; H01L 31/0684; H01L 31/02363

(57) ABSTRACT

A solar cell array is made of a plurality of bifacial PERC solar cells, respectively formed in a semiconductor body, which are electrically interconnected by way of cell connectors. A structured passivation layer is applied on the rear-side surface of the semiconductor body, on which the current collecting rails and contact finger contacting the semiconductor body are provided. A respective cell connector extends at least partially along a longitudinal direction of at least one current collecting rail and electrically contacts this on at least one solder contact via a solder joint. A lateral width of a current collecting rail is at least partially greater than a lateral width of the cell connector covering this current collecting rail.

### FIELD OF THE INVENTION

The present invention relates to a solar cell array.

### TECHNICAL BACKGROUND

The present invention is in the field of so-called bifacial solar cells. Bifacial solar cells are solar cell, in which the front-side as well as the rear-side thereof can be used for power generation. Such solar cells are preferred to be used when the solar cell rear-side is illuminated by scattered light and therefore, the power is generated from scattered light.

PERC (Passivated Emitter and Rear Cell) refers to an innovative solar cell technology by which significantly higher efficiencies can be achieved. In a PERC-solar cell, the semiconductor body includes a structured passivation layer on the rear-side of the semiconductor body, which is provided for reducing recombination losses on the rear-side contact of the solar cell. The contact structure associated thereto is disposed on the passivation layer and locally contacts the rear-side surface of the semiconductor body via the contact openings present in the passivation layer.

The present invention relates to a solar cell array having such a bifacial PERC-solar cell topography, e.g. which is described in DE 20 2015 101 360 U1.

The rear-side contact structure is contacted via so-called cell-connector to the corresponding solder contacts. Therefore, the rear-side contacts can preferably be configured as Aluminum contacts, which is frequently applied as Aluminum-paste in a screen-printing process. However, the problem is that this Aluminum-paste has a low-adhesion to the rear-side passivation of PERC-solar cell, because Aluminum-paste should not include any abrasive glass frits, so that the rear-side passivation is not impaired. This low-adhesion of Aluminum-paste becomes noticeable, for example, in the so-called Ribbon pull-off test of the cell connector, in which during a pull-off test of the ribbon-like cell connector, sometimes unintentionally Aluminum-paste in the region of the current collecting rail is also removed. Thus, the adhesion of Aluminum-paste of the current collecting rail to the cell connector is greater than to the passivation layer. In the actual operation of the solar cell this might lead to that in case of mechanical loads, such as temperature fluctuations or snow and wind loads, crack formation occur in Aluminum contact of the current collecting rail or the surrounding contact fingers, because the cell connector and the solar cell or Aluminum contacts have different coefficients of expansion. The cracks in the contact fingers typically develop parallel to the current collecting rails.

Whereas in unifacial PERC-solar cells in such a case, the power transmission to the solder contact and subsequently to the cell connector is still ensured, because the rear-side Aluminum contact is completely configured and therefore, the current can still freely flow laterally, this is no longer really available in bifacial PERC-solar cells. There is always a risk in bifacial PERC-solar cells that in case of tearing off of the cell connector, the current collecting rail connected thereto and some of the contact fingers connected thereto are also torn off. But certain areas of the solar cell would thereby no longer be electrically connected and thus could no longer contribute—in particular continuously—in power generation.

This is a condition, which has to be avoided.

### SUMMARY OF THE INVENTION

In the light of the above, the object underlying the present invention is to provide an improved bifacial PERC solar cell array.

In accordance with the invention, this object is accomplished by a solar cell array with the features of the claims 1 and 4.

Accordingly, it is provided:
a solar cell array consisting of a plurality of bifacial PERC solar cells provided in a semiconductor body, which are electrically interconnected by means of cell connectors, wherein a structured passivation layer is applied on the rear-side surface of the semiconductor body, on which the current collecting rails and contact finger contacting the semiconductor body are provided, wherein a respective cell connector extends at least partially along the longitudinal direction of at least one current collecting rail and electrically contacts this to at least one solder contact via a solder joint, wherein the lateral width of the current collecting rail is at least partially greater than the lateral width of the cell connector covering this current collecting rail,
solar cell array consisting of a plurality of bifacial PERC solar cells provided in a semiconductor body, which are electrically interconnected by means of cell connectors, wherein a structured passivation layer is applied on the rear-side surface of the semiconductor body, on which the current collecting rails, redundancy fingers and contact fingers contacting the semiconductor body are provided, wherein a respective redundancy finger electrically interconnects a plurality of contact fingers, preferably all contact fingers of a solar cell and in addition to or complementary to the current collecting rails, is configured for conducting current to the solder contact during the operation of the solar cell, wherein a respective cell connector extends at least partially along the longitudinal direction of at least one current collecting rail and electrically contacts this to at least one solder contact via a solder joint, wherein the lateral width of the current collecting rail is at least partially smaller than the lateral width of the cell connector covering this current collecting rail.

The idea of the present invention is to configure the current collecting rails of the bifacial PERC solar cell array such that in case of tearing off of the cell connector and the corresponding underlying current collecting rails associated therewith, the function of the solar cell array is more or less completely preserved, so that a reliable power transmission of the contact fingers in the solder contacts is maintained.

According to a first aspect of the invention, this is realized in that the current collecting rail is configured wider in the middle than the cell connector. In this context, in the middle means that even after tearing-off, sections can be present in which the cell connector is wider than its underlying current collecting rail, however the sections in which the current collecting rail is wider than the corresponding cell connector, overall predominate. In case of tearing-off of the cell connector, in this case due to the middle greater width of the current collecting rail, a part of this current collecting rail would always remain and thus could also contribute in power transmission. The greater width of the rear-side current collecting rail in fact slightly reduces the efficiency of the bifacial solar cell, however this is taken into consideration by the enhanced reliability obtained thereby.

According to a second aspect of the invention, this is realized in that the current collecting rail is configured narrower than the cell connector and additional redundancy fingers are disposed more or less parallel to the current collecting rails. If in case of tearing-off of a cell connector, e.g. several contact fingers would be separated from the current collecting rail, the current flow could nevertheless be conducted to the solder contacts via these redundancy lines. The rear-side current collecting rails could thus be optimized with reference to the area thereof, with regard to the efficiency of the simultaneously higher reliability.

Advantageous configurations and improvements result from the further subordinate claims and from the description with reference to the figures of the drawing.

In a preferred configuration, the current collecting rail is wider than the cell connector over the entire length thereof, thus not only partially. Therefore, the current collecting rail is particularly wider than the cell connector even in the region outside the solder contacts.

In a preferred configuration, at least one redundancy finger per solar cell is provided. A Redundancy finger, which is occasionally also referred to as Redundancy line or Redundancy collecting rail, denotes an electrically conductive contact structure, which electrically interconnects several contact fingers, preferably all contact fingers of a solar cell and which is also configured to conduct current to a solder contact in addition or complementary to the current collecting rails during the operation of the solar cell. Hence, such a redundancy finger kind of forms a redundant current collecting rail, however without—such as the current collecting rail—electrically being contacted via solder contacts and to be directly connected to the cell connectors via these solder contacts. These redundancy fingers additionally improve the reliability of the solar cell array.

In a preferred configuration, the current collecting rail is flared at least in the region of the solder contacts. In particular, it is advantageous if the lateral width of the current collecting rail continuously increases along the longitudinal direction thereof to one such flared solder contact. This takes into account of the higher current density in the region of the solder contact. Moreover, this measure reduces the shadowing losses there as well as the material consumption for the current collecting rail there, due to the narrower current collecting rail outside the solder contact.

In a preferred configuration, the current collecting rails are constantly wide along the entire longitudinal direction thereof, thus also in the region of the solder contacts.

In a preferred configuration, the redundancy finger is disposed at least partially along the longitudinal direction of the current collecting rail thereof. Preferably, the redundancy finger is disposed completely parallel to the current collecting rail and thus does not directly contact the corresponding collecting rail, but only indirectly contacts via the contact fingers.

In a preferred configuration, several redundancy fingers per solar cell are provided, which extend substantially parallel to each other. As a result, the reliability is additionally enhanced and the power-losses are reduced. Moreover, in this way, the area of redundancy fingers and current collecting rails can be optimized with regards to the efficiency at simultaneously higher reliability.

In a preferred configuration, a redundancy finger includes at least one inter connecting section through which the redundancy finger is electrically connected to the current collecting rail.

Preferably, this redundancy finger in the region of the solder contact is electrically connected to the current collecting rail. In case of the failure or tearing off of one or more contact fingers, it is nevertheless ensured by this direct contact that the current collected by these contact fingers, however contributes to power generation through the redundancy fingers. Preferably, the redundancy finger in the region of the interconnection leads radially, i.e. directly towards the current collecting rail or the solder contact thereof. It is particularly preferred if the redundancy finger is led in the region of the interconnection in an arch, i.e. curved with respect to the current collecting rail or the solder contact thereof. In this way, the redundancy finger can include a large number of contact fingers.

In a preferred configuration, at least one redundancy finger is provided, which is disposed between a current collecting rail and a cell border of a respective solar cell. In this case, the failure or tearing-off of the connection of contact finger to the current collecting rail would be most serious, because the current could be collected thereby through another adjoining current collecting rail. This is effectively prevented by means of the redundancy fingers.

In a preferred configuration, the current collecting rail includes several solder contacts along the longitudinal direction thereof, for electrically contacting the cell connectors. As a result, the current densities along the current collecting rails are uniformly divided and power-losses reduced.

In a preferred configuration, at least one current collecting rail is at least partially omitted and/or interrupted between two solder contacts. In addition, the redundancy finger is therefore configured and disposed so as to take over the current transmission to the solder contacts at least partially, particularly completely.

Current collecting rails consisting of Aluminum can be produced particularly inexpensively, for example by means of an Aluminum-paste. However, Aluminum has a low adhesion on the passivation. The present invention now particularly effectively counteracts these low adhesion characteristics. Therefore, the present invention is particularly advantageous in current collecting rails consisting of Aluminum or an Aluminum containing alloy.

In a preferred configuration, the solder contacts include a solderable metal. Preferably, the solderable metal is Silver or an alloy including Silver.

Advantageously, the current collecting rails and/or redundancy fingers and/or contact fingers are applied on the solar cell at least partially, particularly completely by means of a screen-printing process and/or an extrusion printing process and/or Ink-jet process and/or Plating process. The use of such processes has proven as particularly efficient and inexpensive.

In a preferred configuration, at least one redundancy finger includes a width increasing towards the solder contacts.

The above configurations and improvements can be randomly combined with each other, wherever appropriate. Further possible configurations, improvements and implementations of the invention also include combinations not explicitly mentioned previously or described in the following with reference to the features of the exemplary embodiments. In particular, the skilled person may also therefore add individual aspects as improvements or additions to the respective basic form of the present invention.

### SUMMARY OF THE DRAWINGS

The present invention is explained in more details in the following with the help of exemplary embodiments listed in the schematic figures of the drawings. Therefore, these show:

FIG. 1 shows a cross-sectional representation of a bifacial PERC-solar cell array in accordance with the invention;

FIG. 2 partially shows a top-view on the rear-side of a PERC-solar cell in accordance with the invention, according to a first general exemplary embodiment;

FIGS. 3-9 partially shows a top-view on the rear-side of a PERC-solar cell in accordance with the invention, according to further exemplary embodiments.

The accompanying drawings shall impart a broad understanding of the embodiments of the invention. They illustrate embodiments and serve in conjunction with the description of the explanation of principles and concepts of the invention. Other embodiments and many of the advantages mentioned result in view of the drawings. The elements of the drawings are not necessarily shown to scale with respect to each other.

In the figures of the drawing, same, functionally same and similarly working elements, features and components are respectively provided with the same reference numerals, unless explained otherwise.

### DETAILED DESCRIPTION OF THE FIGURES

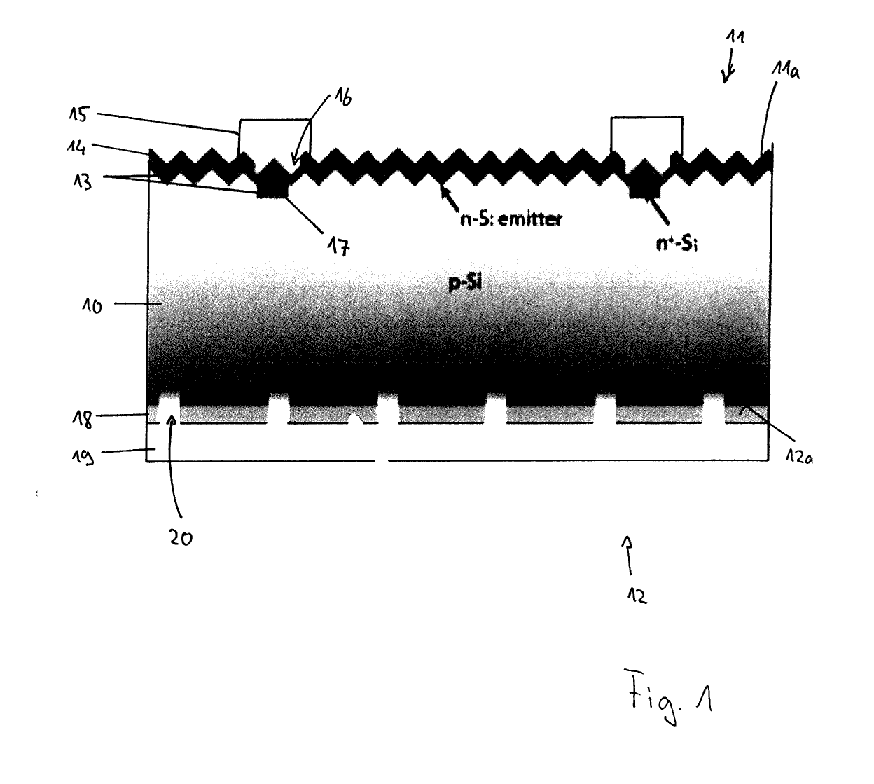

FIG. 1 first shows a cross-sectional representation of a bifacial PERC-solar cell array in accordance with the invention.

A semiconductor body, for example consisting of monocrystalline Silicon is indicated by reference numeral 10. The p-doped semiconductor body 10 includes a front-side 11 and a rear-side 12.

An n-doped front-side emitter 13 is introduced on the front-side 11 in the semiconductor body 10, on which an amorphous Silicon nitride layer 14 is applied as an anti-reflection coating. Further, a front-side contact arrangement 15 is provided on the front-side 11. The front-side contact arrangement 15 includes a plurality of current collecting rails, cell connectors and contact fingers, not represented in more details. The front-side contact arrangement 15 is connected to the front-side emitter 13 through the openings 16 in Silicon nitride layer 14. For an excellent electrical connection, the front-side emitter 13 includes highly doped n-contacts 17 in the region under the openings 16.

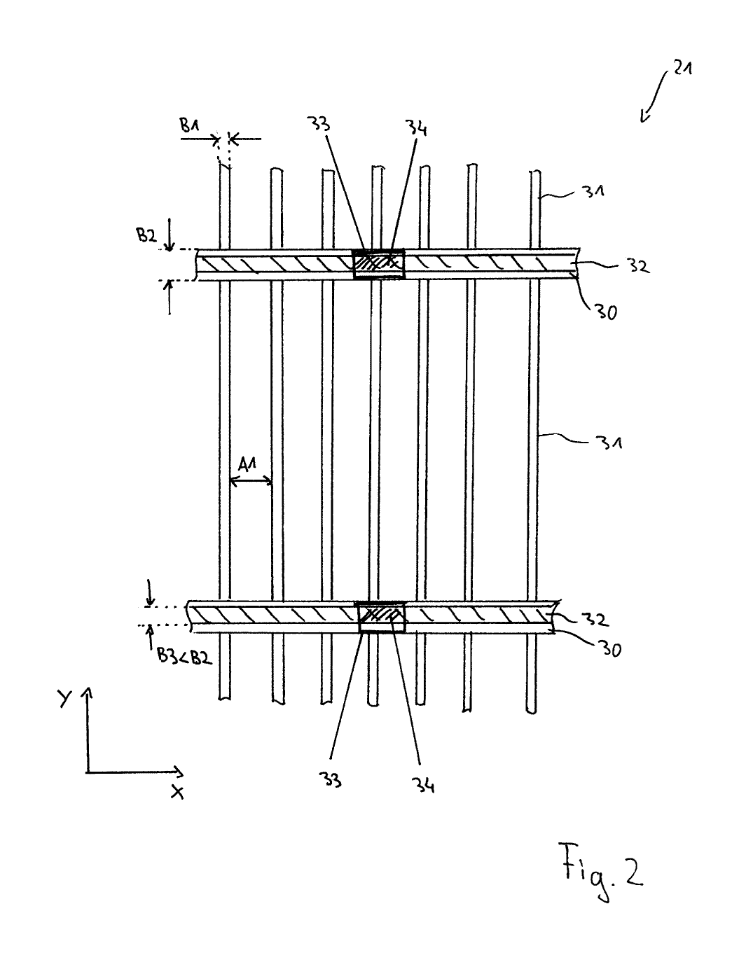

An extensive passivation layer 18 is applied on the semiconductor body 10 on the rear-side 12. This passivation layer 18 is provided for reducing the recombination losses on the rear-side contact of the solar cell. Aluminum-contact structure 19 associated therewith is applied on the passivation layer 18 and locally contacts the rear-side surface 12a of the semiconductor body, in which it extends up to the surface 12a through the contact openings 20 present in the passivation layer 18. This Aluminum-contact structure 19 includes a plurality of current collecting rails, cell connectors, contact fingers, etc. not represented in more details here, the exact arrangement of which is explained in more details in the following with the help of FIGS. 2 to 8. For an excellent electrical connection, the regions under the contact openings 20 have locally diffused, highly doped p-contacts (not shown).

For the sake of clarity, the exact configuration of the emitter structures and the like are not represented in more details in FIG. 1, because these do not describe the core-concept of the present invention.

FIG. 2 partially shows a top-view on the rear-side of a PERC-solar cell of a PERC-Solar cell array in accordance with the invention, according to a first, general exemplary embodiment. The PERC-Solar cell array is indicated here by reference numeral 21.

An Aluminum-contact structure is provided on the rear-side of the semiconductor body, which includes the current collecting rails 30 and contact fingers 31 in a manner known per se.

The contact fingers 31 are disposed substantially parallel to each other in the example shown and form a direct metal-semiconductor contact with the rear-side surface of the semiconductor body. These contact fingers 31 are used for absorbing charge carriers, which are generated in the semiconductor body because of the photovoltaic effect by the incident light.

Each of the contact fingers 31 is electrically connected to at least one current collecting rail 30. These current collecting rails 30, which are often also referred to as Busbar and are generally also disposed parallel to each other, are contacted with the rear-side surface of the semiconductor body in the example shown. However, it is also possible to open the passivation layer under the current collecting rails, so that these are directly connected to the rear-side surface of the semiconductor body via a metal-semiconductor contact and are thus likewise used for absorbing the charge carriers from the semiconductor body. The current collecting rails 30 absorb the charge current absorbed via the different contact fingers 31. The current collecting rails 30 and contact fingers 31 are thus used for collecting and combining the charge carriers generated in the semiconductor body 10.

In order to conduct the charge carriers so collected and also to enable an interconnection of different solar cells, the so-called cell connectors 32 are provided, which are often referred to as series connectors. These cell connector 32, which are typically not a component of the actual solar cell, but of the solar module, are at least partially disposed on the current collecting rails 30 and firmly bonded to these. For example, these cell connectors 32 can be soldered, bonded or pressed on the respective current collecting rail 30 for a firm bonding.

The current collecting rails 30 include at least one solder contact 33 for providing a defined electrical contact. Therefore, the cell connectors 32 on the solder contact 33 are electrically connected to the respective current collecting rail 30 via a solder joint 34.

In the example shown, the cell connectors 32 are disposed along the same longitudinal direction X of the current collecting rails 30 and directly above the current collecting rails 30. On the other hand, the contact fingers 31 are oriented orthogonally to the current collecting rails 30 along the direction Y in the example shown.

Each contact finger 31 has a width 31 and a distance Al from an adjoining contact finger 1G. In accordance with the invention, width D2 of the current collecting rail 30 along the entire longitudinal direction X in the example shown, is greater than width B3 of a cell connector 33 disposed thereon.

Comparatively inexpensive materials such as Aluminum, Nickel and the like, or comparatively highly conductive materials such as Silver can be used as the material for the contact fingers 31 and current collecting rails 30. Preferably, a good solderable material, such as Silver or a suitable Silver alloy is used as solder joint 34.

The contact fingers 31 and current collecting rails 30 are normally manufactured by a strip-shaped conducting paste, e.g. Aluminum conductive paste applied in the screen-printing process and sintering of this applied conductive paste. Alternatively, an extrusion process can also be used. The cell connectors 32 are generally applied by selective soldering in the region of the solder joint 34 on the current collecting rail 30.

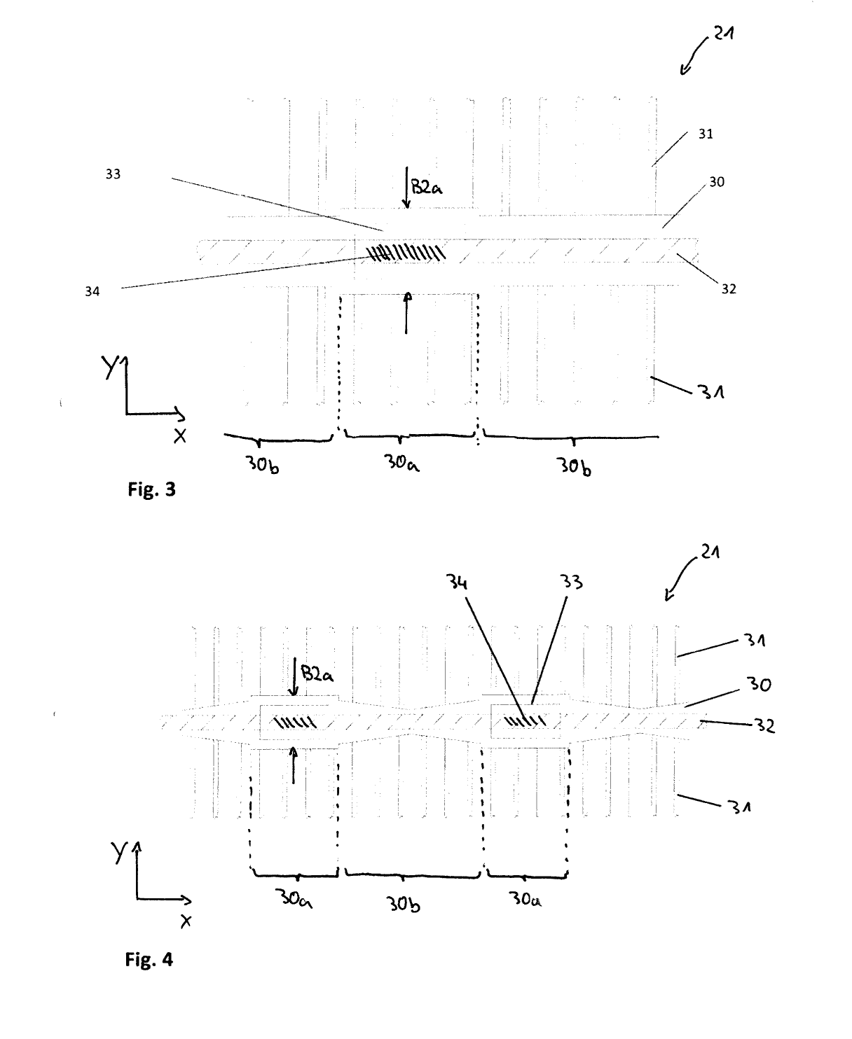

FIGS. 3 and 4 show partial top-view on the rear-side of a PERC-solar cell in accordance with the invention, according to two further exemplary embodiments. In contrast to the exemplary embodiment in FIG. 2, the current collecting rail 30 is flared here in the region of the solder contact 33. In this flared region 30a, the current collecting rail 30 has a width B2a larger than in the remaining regions 30b outside the solder contact 33.

In the example of FIG. 3, the transition from the region 30b to the flared region 30a is in steps.

In the example of FIG. 4 on the other hand, there is a continuous widening of the current collecting rail 30 from the region 30b up to the flared region 30a, while the width B2a in the region of the solder contact 33 then remains constant.

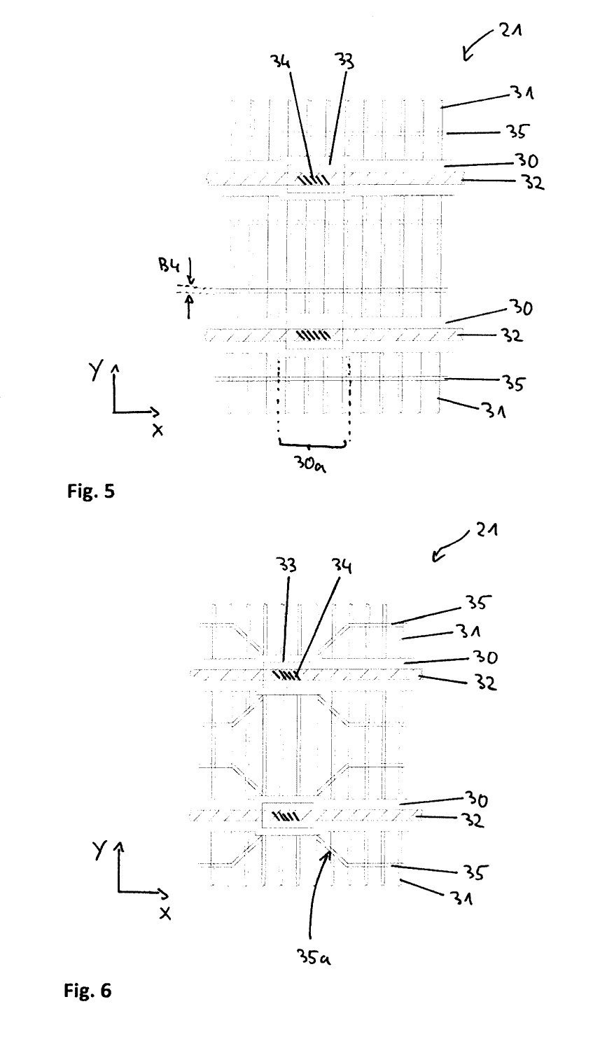

FIG. 5 shows a partial top-view on the rear-side of a PERC-solar cell in accordance with the invention, according to another exemplary embodiment. Here, two parallel extending current collecting rails 30 are shown, which are contacted via contact fingers 31 extending orthogonal thereto. In contrast to the exemplary embodiment in FIG. 3, here redundancy finger 35 extending totally parallel to the current collecting rails 30 are respectively provided, which thus likewise cross the contact fingers 31 and which are indirectly connected to a current collecting rail 30 via these contact fingers 31. These redundancy fingers 35 are configured for conducting the current to the solder contacts 33 in addition or complementary to the current collecting rails during the operation of the solar cell.

B4 denotes the width of a redundancy finger 35. The redundancy fingers 35 can be of constant or even variable width, e.g. a width B4 (not shown here) increasing towards the solder contacts 33.

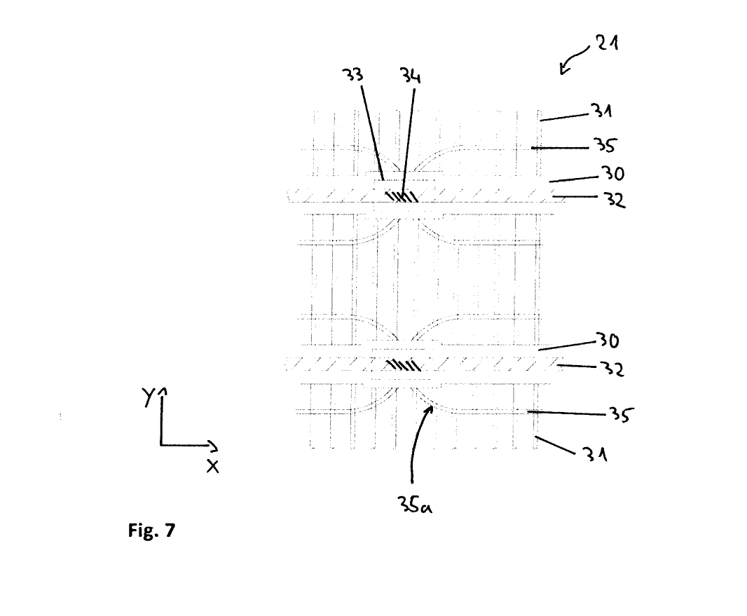

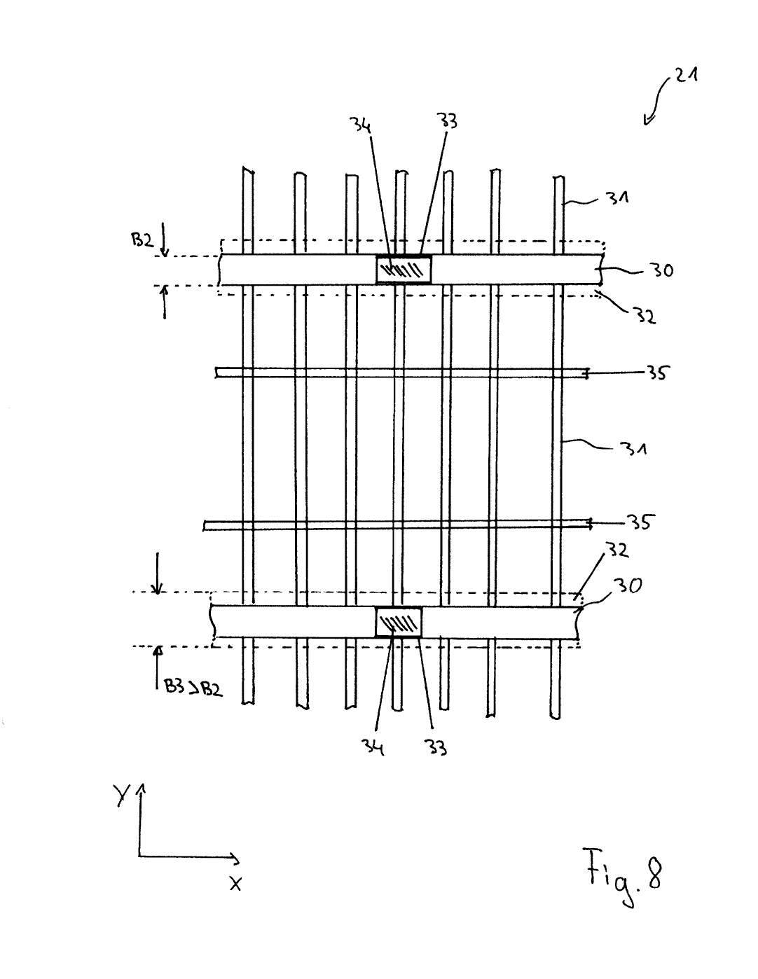

FIGS. 6 and 7 show partial top-views on the rear-side of a PERC-solar cell in accordance with the invention, according to two further exemplary embodiments. In contrast to the exemplary embodiment in FIG. 5, here the redundancy fingers 35 are not completely parallel to the current collecting rail 30. Rather, the redundancy fingers 35 have sections 35a here, through which the redundancy fingers 35 are directly connected to the respective current collecting rail 30 and thus particularly in the region of the solder contacts 33.

In the example of FIG. 6, a respective redundancy finger 35 in the section 35a directly leads to the solder contact 33.

In the example shown of FIG. 7, a respective redundancy finger 35 in the section 35a leads into an arch, thus curved on the solder contact 33.

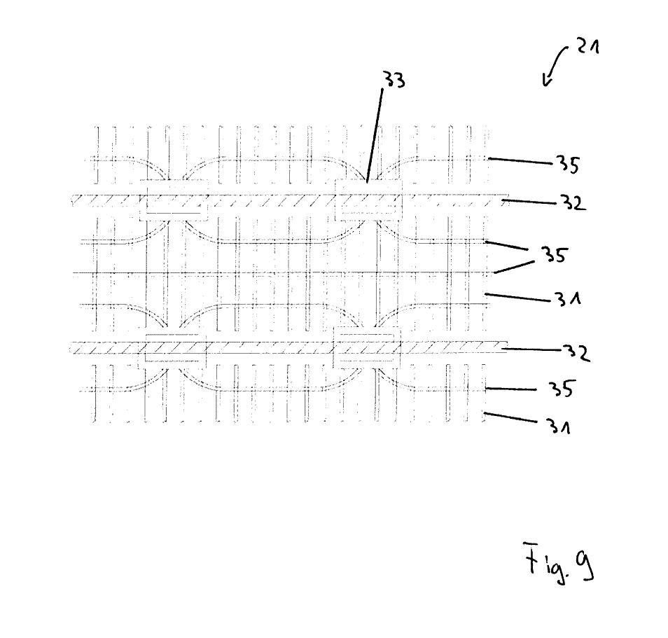

FIG. 8 shows a partial top-view on the rear-side of a PERC-solar cell, according to another exemplary embodiment. In contrast to the exemplary embodiment in FIG. 2, here width B2 of the current collecting rail 30 is smaller than width B3 of the cell connector 32, which is represented dashed here for the sake of clarity. In the exemplary embodiment in FIG. 8, parallel extending redundancy fingers 35 take over a part of the current collecting function of the current collecting rails 30.

Another exemplary embodiment, not shown here, provides that the current collecting rails 35 are completely interrupted or are at least omitted. The current collecting function is predominantly or even completely taken over by the redundancy fingers 35.

FIG. 9 shows a partial top-view on the rear-side of a PERC-solar cell in accordance with the invention, according to another exemplary embodiment. In contrast to the previous exemplary embodiments of FIGS. 2 to 8, a current collecting rail in the conventional sense is completely (or for example only partially dispensed with) dispensed with here. The current collecting function is predominantly or even completely taken over here by the redundancy fingers 35, so that no or only partially available current collecting rails 30 are provided under the cell connectors 32.

Although, the present invention was fully described above with the help of preferred exemplary embodiments, they are not restricted to these, but can be modified in many ways.

In the examples shown, the different contact fingers as well as the different current collecting rails and/or redundancy fingers extend parallel to each other, however this is not absolutely necessary. Also, in the example shown, the current collecting rails are disposed perpendicular to the respective contact fingers, which is also not absolutely necessary.

In particular, the invention is also not restricted to the materials mentioned, though at times they are advantageous, such as the use of Aluminum.

In the same manner, the present invention is also not restricted to the use of p or n-conductive semiconductor materials or p or n-type of solar cells. It goes without saying that by appropriate variation, other conductive types and dopant concentrations can also be used.

The manufacturing process indicated are also used only for explaining the advantages during the manufacture, however the invention is not restricted to these.

In the context of the present invention, above and below means away from the respective surface of the semiconductor body or towards the respective surface of the semiconductor body. The widths and distance data refer to the projection of the respective top-view.

### REFERENCE NUMERALS

10 Semiconductor body

11 Front-side

11a Front-side surface

12 Rear-side

12a Rear-side surface

13 Rear-side emitter

14 Silicon nitride layer, Antireflection coating

15 Rear-side contact arrangement

16 Opening

17 Contact

18 Passivation layer

19 (Aluminum) contact structure

20 Contact opening

21 Solar cell array with bifacial PERC solar cells

30 Current collecting rails, Busbar

30a Flared area of the current collecting rail

30b Region of the current collecting rail

31 Contact finger

32 Cell connector, Series connector

33 Solder contact

34 Solder joint

35 Redundancy finger

35a Section of the redundancy finger

X Longitudinal direction

Y Direction (orthogonal to the longitudinal direction)

A1 Distance of adjoining contact finger

B1 Width of a contact finger

B2 Width of a current collecting rail

B2a Flared width of a current collecting rail

B3 Width of a cell connector

B4 Width of a redundancy finger

1. Solar cell array consisting of a plurality of bifacial PERC solar cells, respectively formed in a semiconductor body, which are electrically interconnected by means of cell connectors,
wherein a structured passivation layer is applied on the rear-side surface of the semiconductor body, on which the current collecting rails and contact finger contacting the semiconductor body are provided,
wherein a respective cell connector extends at least partially along a longitudinal direction of at least one current collecting rail and electrically contacts this on at least one solder contact via a solder joint,
wherein a lateral width of a current collecting rail is at least partially greater than a lateral width of the cell connector covering this current collecting rail.

2. Solar cell array according to claim 1, wherein the current collecting rail is wider than the respective cell connector over the entire length thereof.

3. Solar cell array according to claim 1, wherein at least one redundancy finger is provided, which electrically interconnects a plurality of contact fingers and which is configured for conducting the current to a solder contact in addition or complimentary to the current collecting rails during the operation of the solar cell.

4. Solar cell array according to claim 1, wherein the lateral width of a current collecting rail is flared at least in the region of the solder contacts.

5. Solar cell array according to claim 1, wherein the lateral width of a current collecting rail continuously increases towards a solder contact along the longitudinal direction thereof.

6. Solar cell array according to claim 1, wherein the lateral width of at least one current collecting rail is constant along the entire longitudinal direction thereof.

7. Solar cell array according to claim 1, wherein the redundancy finger is disposed at least partially along the longitudinal direction of a current collecting rail thereof.

8. Solar cell array according to claim 1, wherein a plurality of redundancy fingers are provided per solar cell.

9. Solar cell array according to claim 1, wherein a redundancy finger comprises at least one connecting section, through which the redundancy finger is electrically connected to the current collecting rail.

10. Solar cell array according to claim 1, wherein the redundancy finger leads towards the current collecting rail or solder contact thereof radially and directly or in an arch in the region of the connecting section.

11. Solar cell array according to claim 1, wherein a redundancy finger is disposed between a current collecting rail and a cell border of a respective solar cell.

12. Solar cell array according to claim 1, wherein a current collecting rail comprises a plurality of solder contacts for electrically contacting the cell connectors along the longitudinal direction thereof, and
wherein at least one current collecting rail is omitted or interrupted between two solder contacts and that the redundancy fingers are configured for and disposed for taking over current transmission to the solder contacts at least partially.

13. Solar cell array according to claim 1, wherein the current collecting rails or redundancy fingers or contact fingers consist of Aluminum or an Aluminum containing alloy.

14. Solar cell array according to claim 1, wherein the solder contacts or the solder joints comprise a solderable metal.

15. Solar cell array according to claim 1, wherein the current collecting rails or redundancy fingers or contact fingers are manufactured by a screen-printing process or extrusion printing process or inkjet-process or plating-process.

16. Solar cell array according to claim 1, wherein at least one redundancy finger comprises a width increasing towards the solder contacts.

17. Solar cell array consisting of a plurality of bifacial PERC solar cells respectively formed in a semiconductor body, which are electrically interconnected by means of cell connectors,
wherein a structured passivation layer is applied on a rear-side surface of the semiconductor body, on which the current collecting rails. redundancy fingers and contact fingers contacting the semiconductor body are provided,
wherein a respective redundancy finger electrically interconnects a plurality of contact fingers of a solar cell and is configured for conducting current to a solder contact in addition or complementary to the current collecting rails during the operation of the solar cell,
wherein a respective cell connector extends at least partially along a longitudinal direction of at least one current collecting rail and electrically contacts this on at least one solder contact via a solder joint.

18. Solar cell array according to claim 17, wherein the redundancy finger is at least partially disposed along the longitudinal direction of a current collecting rail.

19. Solar cell array according to claim 17, wherein a redundancy finger is disposed between a current collecting rail and a cell border of a respective solar cell.

20. Solar cell array according to claim 17, wherein at least one redundancy finger comprises a width increasing towards the solder contacts.
